(19) United States
(12) Patent Application Publication
(10) Pub. No.: US 2024/0304451 A1
(43) Pub. Date: Sep. 12, 2024

(54) METHOD FOR FORMING AN OHMIC CONTACT ON A GERMANIUM-TIN BASED LAYER

(71) Applicant: COMMISSARIAT À L’ENERGIE ATOMIQUE ET AUX ENERGIES ALTERNATIVES, PARIS (FR)

(72) Inventors: Nicolas COUDURIER, GRENOBLE CEDEX 9 (FR); Philippe RODRIGUEZ, GRENOBLE CEDEX 9 (FR)

(21) Appl. No.: 18/597,346

(22) Filed: Mar. 6, 2024

(30) Foreign Application Priority Data
Mar. 6, 2023 (FR) 2302062

(51) Int. Cl. H01L 21/285; C23C 14/16; C23C 14/30; C23C 14/34; C23C 14/46

(52) U.S. Cl. CPC H01L 21/2855; C23C 14/165; C23C 14/30; C23C 14/3464; C23C 14/46

(57) ABSTRACT

A method for forming an ohmic contact on a layer of semiconductor material including germanium and tin. The method includes depositing a nickel-germanium layer onto the semiconductor material layer by a physical vapour deposition technique.

### CROSS-REFERENCE TO RELATED APPLICATIONS

This application claims priority to French Patent Application No. 2302062, filed Mar. 6, 2023, the entire content of which is incorporated herein by reference in its entirety.

### FIELD

The technical field of the invention is that of forming an ohmic contact on a layer of semiconductor material comprising germanium and tin, typically a layer of germanium-tin (GeSn) alloy or silicon-germanium-tin (SiGeSn) alloy.

### BACKGROUND

GeSn and SiGeSn alloys have emerged as promising materials for making microelectronic devices such as field-effect transistors. For example, GeSn can be used to form a high mobility channel in metal-oxide-semiconductor field effect transistors (MOSFETs) or in tunnel field effect transistors (TFETs). It can also be used in the drain and source regions of a MOSFET to generate compressive stress in a germanium channel.

Since the addition of tin to the crystalline structure of germanium above an atomic percentage of about 10% makes it possible to obtain a direct bandgap semiconductor material, the GeSn alloy is also used to form the active (emitter/receiver) layers of optoelectronic devices. As examples of optoelectronic devices, p-i-n photodetectors, heterojunction light-emitting diodes and, more recently, optically and electrically pumped lasers may be mentioned.

Whatever the targeted application, low-resistivity ohmic contacts with the GeSn layer are necessary to obtain high-performance devices.

Nickel-based contacts have been provided because nickel allows the formation of an Ni(GeSn) intermetallic alloy at a temperature compatible with microelectronic and optoelectronic devices, this intermetallic alloy further having a low value of specific contact resistivity (ρ_{SC}) with the GeSn layer and a low value of square resistance (Rs).

The articles [“Formation of Ni(Ge₁₋ₓSnₓ) layers with solid-phase reaction in Ni/Ge₁₋ₓSnₓ/Ge systems”, Tsuyoshi Nishimura et al, Solid-State Electronics, Volume 60, Issue 1, pp. 46-52, 2011] and [“Impact of alloying elements (Co, Pt) on nickel stanogermanide formation”, Andrea Quintero et al, Materials Science in Semiconductor Processing, 108, 104890, 2020] thus describe methods for forming ohmic contacts by solid-state reaction of a nickel layer on a GeSn layer.

FIG. 1 schematically represents the ohmic contact formation method described in the article by A. Quintero et al. The formation method comprises two steps:
a step S1 of depositing a nickel layer 11 onto a GeSn layer 12 by sputtering, the GeSn layer 12 having been previously formed by epitaxy on a germanium buffer layer 13, itself epitaxially grown on a silicon substrate 14; and
a step S2 of annealing the stack thus obtained at a temperature of between 200° C. and 550° C. for 30 s, to form an Ni(GeSn) layer 15 in ohmic contact with the GeSn layer 12.

As indicated in the aforementioned articles, Ni(GeSn) contacts have low thermodynamic stability (leading to low thermal stability) due to segregation of the tin atoms and agglomeration of the Ni(GeSn) grains. These segregation and agglomeration phenomena are emphasised when the tin content of the GeSn layer increases.

### SUMMARY

An aspect of the invention is to form an ohmic contact having better thermal stability on a layer of semiconductor material comprising germanium and tin.

According to an embodiment of the invention, this objective is achieved by providing an ohmic contact formation method comprising a step of depositing a nickel-germanium layer onto the semiconductor material layer by means of a physical vapour deposition technique.

In an embodiment, the physical vapour deposition technique is selected from evaporation techniques, especially thermal evaporation and electron beam evaporation (EBPVD), sputtering techniques, especially cathode sputtering and ion beam sputtering (IBD), ion beam assisted deposition (IBAD) and pulsed laser deposition (PLD).

In a first embodiment of the formation method, the nickel-germanium layer is formed by sputtering a single nickel-germanium target.

In a second embodiment, the nickel-germanium layer is formed by co-sputtering a nickel target and a germanium target.

The formation method may further comprise a step of annealing the nickel-germanium layer at a temperature less than or equal to 350° C., or, on the contrary, be devoid of an annealing step.

The formation method according to an embodiment of the invention may also have one or several of the characteristics below, considered individually or according to any technically possible combinations:
the semiconductor material is germanium-tin or silicon-germanium-tin;
the semiconductor material has an atomic percentage of tin less than or equal to 25%;
the semiconductor material layer belongs to a semiconductor device of the field-effect transistor, photodetector, light-emitting diode or laser type.

### BRIEF DESCRIPTION OF THE FIGURES

Other characteristics and benefits of the invention will appear clearly from the description given below, by way of indicating and in no way limiting purposes, with reference to the following figures:

FIG. 1 schematically represents an ohmic contact formation method according to the prior art;

FIG. 2 schematically represents a first embodiment of the ohmic contact formation method according to the invention;

FIG. 3 schematically represents a second embodiment of the ohmic contact formation method according to the invention; and

FIG. 4 represents the specific contact resistivity of a plurality of ohmic contacts obtained using the formation method according to an embodiment of the invention, with or without an annealing step after the deposition step.

For the sake of clarity, identical or similar elements are marked by identical reference signs throughout the figures.

### DETAILED DESCRIPTION

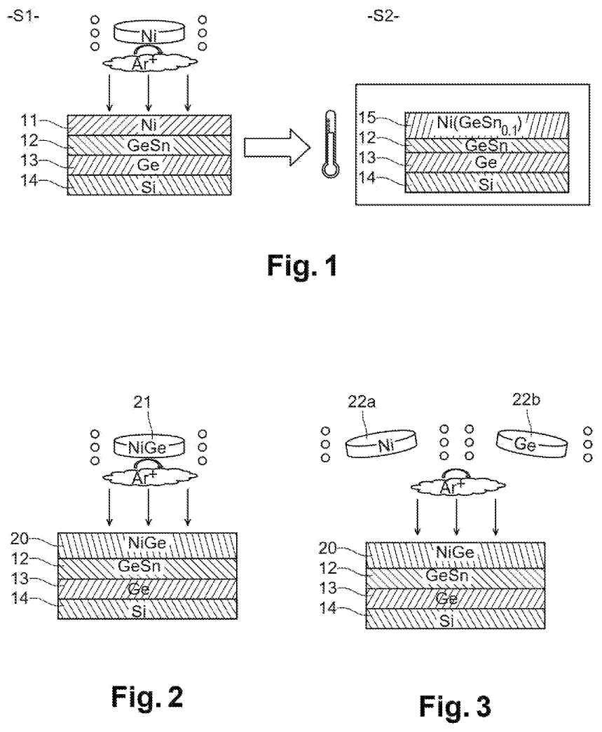

FIGS. 2 and 3 schematically represent two embodiments of a method for forming an ohmic contact on a semiconductor layer 12.

The semiconductor layer 12 is comprised of a semiconductor material comprising germanium (Ge) and tin (Sn), such as the germanium-tin alloy (GeSn) or the silicon-germanium-tin alloy (SiGeSn). It can be disposed on a germanium buffer layer 13, itself disposed on a silicon substrate 14. The germanium buffer layer 13 and the semiconductor layer 12 have, for example, been formed (successively) by epitaxy on a silicon substrate 14. Alternatively, the semiconductor layer 12 may be directly epitaxially grown on a germanium substrate.

In an embodiment, the semiconductor layer 12 belongs to a semiconductor device which may be a field effect transistor (for example, a MOSFET, TFET, etc.), a photodetector (for example, a p-i-n photodetector), a light-emitting diode (for example, a heterojunction light-emitting diode) or a laser (for example, an electrically and optically pumped laser). It may especially form an active layer of the semiconductor device, such as a channel layer in the case of an FET or a radiation emission or reception layer in the case of optoelectronic devices (photodetector, light-emitting diode and laser). The material of the semiconductor layer 12 has an atomic percentage of tin which is beneficially less than or equal to 25% (but not zero), and for example between 10% and 15% (to obtain a direct-gap semiconductor material).

In a manner common to both embodiments, the ohmic contact formation method comprises a step of depositing by physical vapour deposition (PVD) a nickel-germanium alloy (NiGe) layer 20 onto the semiconductor layer 12.

The NiGe layer 20, which is electrically conductive, forms an ohmic contact with the GeSn-based semiconductor layer 12, without the need for annealing to initiate a chemical reaction. It also has the benefit of being thermally stable, unlike a layer composed of the intermetallic alloy Ni(GeSn) and obtained by solid-state reaction of a nickel layer. In particular, when subjected to heat treatment (for example during a subsequent step in the method for manufacturing the semiconductor device), the NiGe layer 20 does not undergo the segregation or agglomeration phenomena of the method of prior art. The morphology and crystalline phases of the NiGe layer 20 hardly change over time. Thus, the NiGe/(Si)GeSn ohmic contact, due to its thermodynamic stability, has better resistance to integration than the Ni(GeSn)/(Si)GeSn ohmic contact.

In the first embodiment represented by FIG. 2, the NiGe layer 20 is deposited by sputtering a single target 21 consisting of the NiGe alloy. This type of deposition is particularly simple to implement. However, it is not possible to control stoichiometry of the NiGe layer 20, as this is set by the stoichiometry of the target 21. In an embodiment. the NiGe target 21 comprises, in atomic percentage (at. %), 40% to 60% germanium and 60% to 40% nickel, and in an embodiment 50% germanium and 50% nickel.

In the second embodiment represented by FIG. 3, the NiGe layer 20 is deposited by co-sputtering (or simultaneously sputtering) a first target 22a consisting of nickel and a second target 22b consisting of germanium. This second embodiment makes it possible to easily control composition of the NiGe layer 20 deposited by adapting sputtering parameters of the two targets. Using two targets is also more beneficial in terms of cost, as the Ni target 22a and the Ge target 22b are not consumed at the same rate and degrade less quickly over time than a single NiGe target. In addition, this allows better control of the method over time.

The sputtering technique employed in either of these embodiments may be cathode sputtering (using argon plasma, for example, as represented in FIGS. 2-3) or ion beam sputtering (also known as ion beam deposition, or IBD).

By way of example, the NiGe layer 20 may be deposited at a rate of about 0.25 nm/s by sputtering a single NiGe target (FIG. 2) using the Alliance Concept CT200 sputtering reactor, under the following conditions:
an argon flow rate of 50 sccm (abbreviation of Standard Cubic Centimeter per Minute, that is the number of cm³ of gas flowing per minute under standard conditions of pressure and temperature, that is, at a temperature of 0° C. and a pressure of 1013.25 hPa);
a pressure in the reactor chamber equal to 2 mTorr, that is, 0.267 Pa;
a power output by the DC generator in the reactor equal to 1000 W;
a rotation speed of the substrate holder equal to 15 rpm; and
a substrate holder temperature equal to 70° C.

XRD (X-Ray Diffraction) analysis of the NiGe layer 20 deposited by sputtering revealed the presence of four crystalline phases ((111), (112), (211) and (013)), in other words a polycrystalline state.

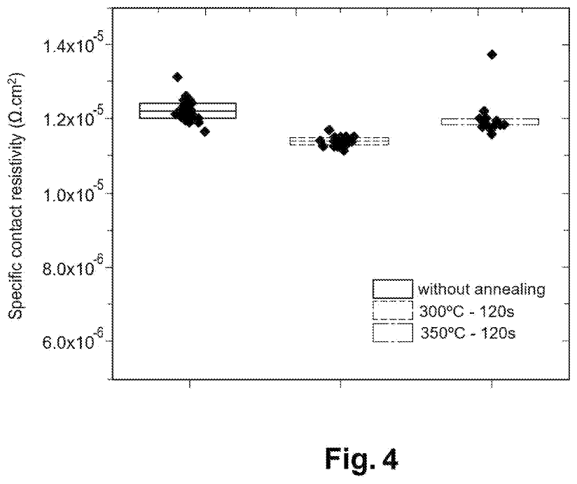

FIG. 4 represents measurements of the specific contact resistivity for three sets of NiGe/GeSn contact samples:
a first series of samples for which deposition of the NiGe layer 20 is not followed by an annealing step;
a second series of samples for which deposition of the NiGe layer 20 is followed by an annealing step at 300° C. for 120 s; and
a third series of samples for which deposition of the NiGe layer 20 is followed by an annealing step at 350° C. for 120 s.

These measurements show that the NiGe/GeSn ohmic contacts obtained using the method according to the invention have a specific contact resistivity comparable to that of Ni(GeSn)/GeSn contacts and that, furthermore, this specific contact resistivity is only very slightly improved by annealing the NiGe layer at a temperature less than or equal to 350° C.

Thus, unlike the formation method by solid-state reaction of prior art, the formation method according to the invention can be devoid of an annealing step after the PVD step. It is then quicker (and cheaper) to implement. Beneficially, the formation method according to the invention comprises only the PVD step (single-step method).

Alternatively, the NiGe layer 20 may be subjected to annealing at a temperature less than or equal to 350° C. in order to improve the specific contact resistivity by a few percent.

PVD techniques other than sputtering techniques may be employed to form an NiGe ohmic contact on the semiconductor layer 12. By way of examples, evaporation techniques, especially thermal evaporation and electron beam evaporation (also known as electron beam PVD, or EBPVD) can be mentioned. The evaporation equipment may comprise a single crucible containing a NiGe source (for example in the form of pellets or billets) or two crucibles, one containing a nickel source and the other containing a germanium source.

The NiGe layer 20 can also be obtained by ion beam-assisted deposition (IBAD) or pulsed laser deposition (PLD), using a single NiGe target.

It will be appreciated that the various embodiments and aspects of the inventions described previously are combinable according to any technically permissible combinations. For example, various aspects of the present disclosure may be used alone, in combination, or in a variety of arrangements not specifically described in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Having described above several aspects of at least one embodiment, it is to be appreciated various alterations, modifications, and improvements will readily occur to those skilled in the art. Such alterations, modifications, and improvements are intended to be object of this disclosure. Accordingly, the foregoing description and drawings are by way of example only.

1. A method for forming an ohmic contact on a layer of a semiconductor material comprising germanium and tin, comprising depositing a nickel-germanium layer onto the semiconductor material layer by a physical vapour deposition technique.

2. The method according to claim 1, wherein the physical vapour deposition technique is selected from evaporation techniques, especially thermal evaporation and electron beam evaporation (EBPVD), sputtering techniques, especially cathode sputtering and ion beam sputtering (IBD), ion beam assisted deposition (IBAD) and pulsed laser deposition (PLD).

3. The method according to claim 1, wherein the nickel-germanium layer is formed by sputtering a single nickel-germanium target.

4. The method according to claim 1, wherein the nickel-germanium layer is formed by co-sputtering a nickel target and a germanium target.

5. The method according to claim 1, further comprising annealing the nickel-germanium layer at a temperature less than or equal to 350° C.

6. The method according to claim 1, devoid of an annealing step.

7. The method according to claim 1, wherein the semiconductor material is germanium-tin (GeSn) or silicon-germanium-tin (SiGeSn).

8. The method according to claim 1, wherein the semiconductor material has an atomic percentage of tin less than or equal to 25%.

9. The method according to claim 1, wherein the semiconductor material layer belongs to a semiconductor device of the field-effect transistor, photodetector, light-emitting diode or laser type.
